(19) United States
(12) Patent Application Publication
(10) Pub. No.: US 2011/0074441 A1
(43) Pub. Date: Mar. 31, 2011

(54) Low Capacitance Signal Acquisition System

(75) Inventors: Josiah A. Bartlett, Forest Grove, OR (US); Ira G. Pollock, Hillsboro, OR (US); Daniel G. Knierim, Beaverton, OR (US); Lester L. Larson, Portland, OR (US); Scott R. Jansen, Beaverton, OR (US); Kenneth P. Dobyns, Beaverton, OR (US); Michael Duane Stevens, Hillsboro, OR (US)

(73) Assignee: TEKTRONIX, INC., Beaverton, OR (US)

(21) Appl. No.: 12/571,236

(22) Filed: Sep. 30, 2009

(51) Int. Cl. G01R 35/00; G01R 27/26

(52) U.S. Cl. 324/601; 324/684

(57) ABSTRACT

A low capacitance signal acquisition system has a signal acquisition probe having a low capacitance input circuit coupled to a compensation amplifier in a signal processing instrument via a signal cable. The low capacitance input circuit, the signal cable and the signal processing instrument input have mismatched time constants with the compensation amplifier having feedback loop circuitry providing adjustable gain and pole-zero pairs for maintaining flatness over the low capacitance signal acquisition system frequency bandwidth.

### BACKGROUND OF THE INVENTION

The present invention relates generally to acquiring signal from a device under test and more particularly to a low capacitance signal acquisition system having reduced loading of the device under test.

Traditional passive voltage probes 10 generally consist of a resistive-capacitive parallel network 12 at the probe tip 14, shown as R_{T} and C_{T} in FIG. 1, coupled via a resistive center conductor cable 16 to compensation circuitry 18 in a compensation box. The compensation circuitry 18 has resistive and capacitive elements, R_{C1} in series with the cable 16 and R_{C2} in series with variable capacitor C_{C}, which terminates the cable 16 to minimize reflections and provide a measurement test instrument 22, such as an oscilloscope, spectrum analyzer, logic analyzer and the like, with a flat frequency response. The variable compensation capacitor C_{C} is user adjustable to match individual oscilloscope channels. Resistive element R_{C1} provides resistive cable 16 termination matching into the oscilloscope input at high frequencies (cable Z₀≈155Ω). R_{C2} in series with variable capacitor C_{C} improves the cable termination into the capacitive load in the oscilloscope. The compensation circuitry 18 is coupled to the input circuitry 20 of a measurement test instrument 22. Generally, the input circuitry 20 of an oscilloscope includes a termination resistive-capacitive network 24, shown as R_{TS} and C_{TS}, with associated input attenuation circuitry (not shown) that terminates the oscilloscope input in 1 MΩ. The output of the input attenuation circuitry is coupled to the input of a preamplifier 26.

The tip resistance R_{T} and the termination resistance R_{TS} form a voltage divider attenuation network for DC to low frequency input signals. To accommodate a wide frequency range of input signals, the resistive voltage divider attenuation network is compensated using a shunt tip capacitor C_{T} across the tip resistive element R_{T} and a shunt termination capacitor C_{TS} across termination resistive element R_{TS}. To obtain a properly compensated voltage divider, the time constant of the probe tip resistive-capacitive parallel network 12 must equal the time constant of the termination resistive-capacitive parallel network 24.

Properly terminating the resistive cable 16 in its characteristic impedance requires adding a relative large shunt capacitance C_{C} to the compensation network 18. This is in addition to the bulk cable capacitance C_{CABLE}. For example, the tip resistance R_{T} and capacitance C_{T} for a P2222 10× Passive Probe, manufactured and sold by Tektronix, Inc., Beaverton, Oreg., is selected to give a 10× divide into the oscilloscopes input impedance of 1 MΩ. The minimum tip capacitance C_{T}, neglecting any other parasitic capacitance, is one tenth the sum of the cable bulk capacitance C_{CABLE} and the characteristic capacitance C_{TS}. The tip capacitance of C_{T} is on the order of 8 pf to 12 pf for the above stated parameters. The input capacitance C_{T} is driven by the circuit being monitored and therefore represents a measure of how much the probe loads the circuit.

U.S. Pat. No. 6,483,248, shown in FIG. 2, teaches a wideband probe using pole-zero cancellation. A probe tip network of resistor Rₜᵢₚ and capacitor Cₜᵢₚ in series with resistor R_{tab} and capacitor C_{tab} are coupled to a compensation network via a coaxial cable 40. The capacitor C_{tab} represents the capacitance in the tip circuit, such as a trace on a circuit board, a coaxial cable or the like. A resistor Rₑ is connected in series between the cable and an inverting input terminal of an operational amplifier 42. The non-inverting input is coupled to a common ground. Connected between the input terminal and the output terminal of the operational amplifier 42 is a parallel combination of a resistor R_{fb} and a capacitor C_{fb} with resistor Rₚₖ in series with C_{fb}. The parallel tip resistor Rₜᵢₚ and capacitor Cₜᵢₚ create a zero and the combination of resistor R_{tab} and capacitor C_{tab} create a pole. A pole is created by resistor R_{fb} and capacitor C_{fb} in the compensation network and a zero is created by resistor Rₚₖ and capacitor C_{fb}. The zero and pole created in the probe tip network are cancelled by the pole and zero in the compensation network. The teaching states that the time constants of the two RC networks must be equal so that the zeros and poles balance out and has a constant gain.

### SUMMARY OF THE INVENTION

Accordingly, the present invention is a low capacitance signal acquisition system having a low capacitance input circuit disposed in a signal acquisition probe and coupled via a signal cable to input circuitry of a signal processing instrument. The input circuitry of the signal processing instrument is coupled to a compensation amplifier having feedback loop circuitry. The low capacitance input circuit, the signal cable and the input circuitry of the signal processing instrument input have mismatched time constants with the feedback loop circuitry and compensation amplifier providing adjustable gain and pole-zero pairs for maintaining flatness over the low capacitance signal acquisition system frequency bandwidth.

The compensation amplifier preferably is an inverting amplifier with the feedback loop circuitry having a variable gain voltage source, in the form of a variable gain amplifier, coupled in series with at least a first resistive element and a first capacitive element. The feedback loop circuitry further has a second series coupled capacitive and resistive elements in parallel with a third series coupled capacitive and resistive elements forming a split pair of poles and zeros.

The input circuitry of the signal processing instrument is preferably attenuator circuitry. Switching circuitry is disposed in the signal processing instrument for selectively coupling the low capacitance input circuit to the compensation amplifier via the attenuator circuitry and for selectively coupling a resistive-capacitive network between the low capacitance input circuit and the attenuator circuitry.

The low capacitance input circuit has at least a first resistive element coupled in parallel with a capacitive element wherein the capacitive element has a capacitance producing a time constant mismatch. Additionally, the low capacitance input circuit may be constructed of a plurality of first resistive elements in parallel with a plurality of capacitive elements to produce a high voltage signal acquisition probe.

Various alternative embodiments are envisioned for the low capacitance signal acquisition system. In one alternative embodiment, one of the second or third series coupled capacitive and resistive elements may be replaced with a second variable gain voltage source coupled in series with at least a second resistive element and a second capacitive element and a series coupled third capacitive element and third resistive element. In a further embodiment, the compensation amplifier has a first amplifier coupled to the input circuitry and has a first feedback loop providing adjustable low band, midband and high band gain for the low capacitance signal acquisition system. A second amplifier is coupled to the output of the first amplifier and has feedback loop circuitry providing poles-zero pairs for maintaining flatness over the low capacitance signal acquisition system frequency bandwidth.

A calibration process for the low capacitance signal acquisition system includes the steps of acquiring digital values of a fast edge signal as a calibration waveform using the signal acquisition probe and the signal processing instrument, determining a measured error value between a fast edge signal reference calibration waveform stored in the signal processing instrument and the calibration waveform at a common location on the waveforms, determining a measured error factor as a function of the measured error and at the common location, and applying the measured error factor to a register value of an appropriate feed back loop register in a plurality of registers in feedback loop circuitry of a compensation amplifier. The measured error value and the measured error factor for each common location of the calibration waveform and the calibration reference waveform is then determined. After the measured error value and the measured error factor has been determined for the last common location on the calibration waveform and the calibration reference waveform, a new set of digital values of a fast edge signal are acquired as the calibration waveform. The new calibration waveform is compared with calibration specifications to verify the calibration. If the calibration is within the calibration specifications, the register values in the plurality of registers in feedback loop circuitry of a compensation amplifier are stored and the successful result of the calibration process is displayed.

If the calibration waveform is not within the calibration specifications, then a determination is made on whether the calibration process has exceeded a timed out value. If the calibration process has not timed out, then the common location on the waveforms is set to the initial location. The measured error value and the measured error factor for each common location of the calibration waveform and the calibration reference waveform is then determined. After the measured error value and the measured error factor has been determined for the last common location on the calibration waveform and the calibration reference waveform, a new set of digital values of a fast edge signal are acquired as the calibration waveform. The new calibration waveform is compared with calibration specifications to verify the calibration. If the new calibration waveform is still not within the calibration specifications and the calibration process has timed out, then the initial values in the plurality of registers in the feedback loop circuitry of a compensation amplifier prior to the calibration process are stored, and the unsuccessful result of the calibration process is displayed.

The acquiring of the digital values of the fast edge signal as the calibration waveform includes the additional steps of attaching the signal acquisition probe to the signal processing instrument. The signal processing instrument detects the presence or absence of a probe memory in the signal acquisition probe, and loads stored contents of probe memory into the signal processing instrument if the probe memory is present. The signal processing instrument detects the presence of probe calibration constants stored in the probe memory, and applies the probe calibration constants to appropriate register values in the plurality of registers in the in feedback loop circuitry of a compensation amplifier. If the signal acquisition probe does not have a probe memory, then nominal register values are applied to the plurality of registers in the in feedback loop circuitry of a compensation amplifier.

The calibration process may be implemented in the frequency domain by converting the digital values of a fast edge signal calibration waveform to a frequency domain representation using a Fast Fourier Transform and determining a measured error value between a frequency domain representation of fast edge signal reference calibration waveform stored in the signal processing instrument and the frequency domain representation of the calibration waveform at common frequency locations on the waveforms. The frequency domain representation of fast edge signal reference calibration waveform is stored as S-parameters.

The objects, advantages and novel features of the present invention are apparent from the following detailed description when read in conjunction with appended claims and attached drawings.

### BRIEF DESCRIPTION OF THE DRAWING FIGURES

FIG. 1 is a representative schematic diagram of a prior art passive probe.

FIG. 2 is representative schematic diagram of another prior art probe circuit.

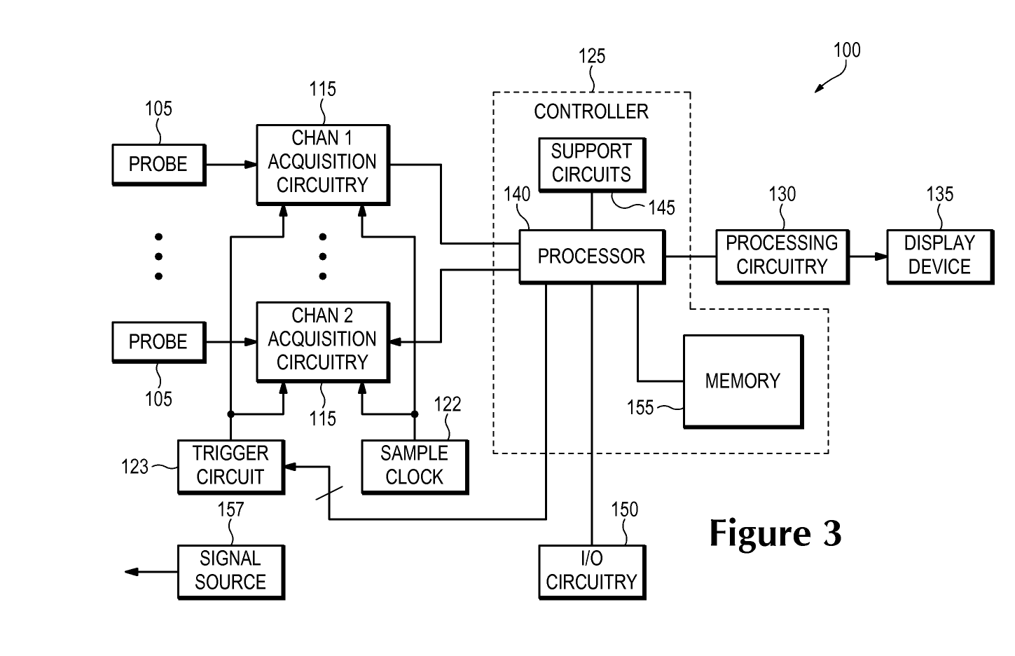

FIG. 3 is a representative block diagram of a signal processing instrument in the low capacitance signal acquisition system according to the present invention.

FIG. 4 is a representative schematic diagram of the low capacitance signal acquisition system according to the present invention.

FIG. 5 shows representative frequency responses of the low capacitance signal acquisition system with and without feedback crossover compensation.

FIGS. 6A and 6B show a calibration process flow chart for calibrating the low capacitance signal acquisition system of the present invention.

FIG. 7 is a representative schematic of the attenuator circuitry in the low capacitance signal acquisition system of the present invention.

FIG. 8 is a schematic representation of the high voltage signal acquisition probe in the low capacitance signal acquisition system of the present invention.

FIG. 9 is an alternate embodiment of the low capacitance signal acquisition system of the present invention.

FIG. 10 is a further embodiment of the low capacitance signal acquisition system of the present invention.

### DESCRIPTION OF THE INVENTION

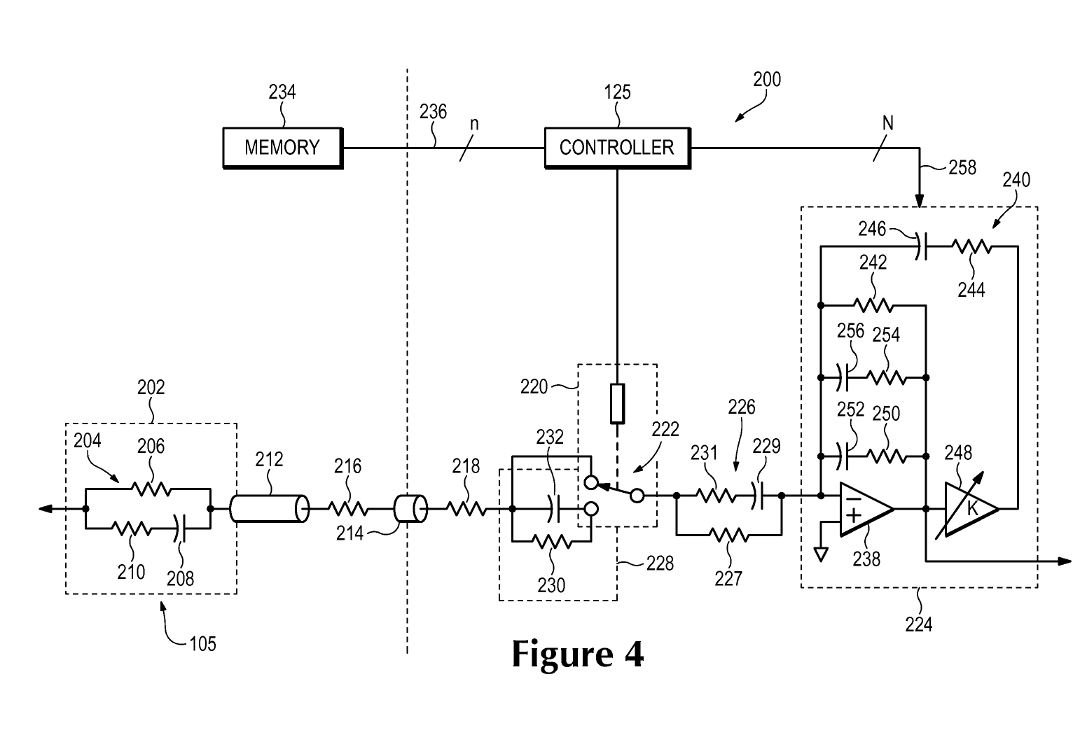

The present invention is directed to a low capacitance signal acquisition system suitable for use with a signal processing instrument, such as oscilloscopes, logic analyzers and the like. The present invention will be described below with respect to an oscilloscope. FIG. 3 depicts a high level block diagram of an oscilloscope 100 used as part of the low capacitance signal acquisition system of the subject invention. Generally, oscilloscopes 100 include multiple signal channels with each signal channel having an input on which are connected various types of signal acquisition probes 105, such as passive and active voltage probes, current probes, and the like, for acquiring electrical signals from a device under test (DUT). The oscilloscope 100 signal channel inputs are coupled to respective signal channel acquisition circuitry 115. The respective acquisition circuitry 115 sample their respective input signals in accordance with a sample clock provided by an internal sample clock generator 122.

The acquisition circuitry 115 each include a preamplifier, analog-to-digital conversion circuitry, triggering circuitry, decimator circuitry, supporting acquisition memory, and the like. The acquisition circuitry 115 operate to digitize, at a sample rate, “SR”, one or more of the signals under test to produce one or more respective sample streams suitable for use by controller 125 or processing circuitry 130. The acquisition circuitry 115, in response to commands received from the controller 125, changes preamplifier feedback values; trigger conditions, decimator functions, and other acquisition related parameters. The acquisition circuitry 115 communicates its respective resulting sample stream to the controller 125.

A trigger circuit 123 is shown separate from the acquisition circuitry 115 but one skilled in the art will realize that it could be internal to the acquisition circuitry. The trigger circuit 123 receives trigger parameters, such as trigger threshold level, hold off, post trigger acquisition, and the like, from the controller 125 in response to user input. The trigger circuit 123 conditions the acquisition circuitry 115 for capturing digital samples of the signal under test from the DUT.

The controller 125 operates to process the one or more acquired sample streams provided by the acquisition circuitry 115 to generate respective sample stream data associated with one or more sample streams. That is, given desired time per division and volts per division display parameters, controller 125 operates to modify or rasterize the raw data associated with an acquired sample stream to produce corresponding waveform data having the desired time per division and volts per division parameters. The controller 125 may also normalize waveform data having non-desired time per division, volts per division, and current per division parameters to produce waveform data having the desired parameters. The controller 125 provides the waveform data to processing circuitry 130 for subsequent presentation on display device 135.

The controller 125 of FIG. 3 preferably comprises a processor 140, such as a PowerPC™ Processor, manufactured and sold by Motorola, Inc., Schaumburg, Ill., support circuits 145 and memory 155. Processor 140 cooperates with conventional support circuitry 145, such as power supplies, clock circuits, cache memory, buffer/expanders, and the like, as well as circuits that assist in executing software routines stored in memory 155. As such, it is contemplated that some of the process steps discussed herein as software processes may be implemented within hardware, for example, as circuitry that cooperates with processor 140 to perform various steps. Controller 125 also interfaces with input/output (I/O) circuitry 150. For example, I/O circuitry 150 may comprise a keypad, pointing device, touch screen, or other means adapted to provide user input and output to the controller 125. The controller 125, in response to such user input, adapts the operations of acquisition circuitry 115 to perform various data acquisitions, triggering, processing, and display communications, among other functions. In addition, the user input may be used to trigger automatic calibration functions or adapt other operating parameters of display device 135, logical analysis, or other data acquisition devices.

Memory 155 may include volatile memory, such as SRAM, DRAM, among other volatile memories. Memory 155 may also include non-volatile memory devices, such as a disk drive or a tape medium, among others, or programmable memory, such as an EPROM, among others. A signal source 157 generates an output signal for probe compensation. In the preferred embodiment of the present invention, the output signal is a fast edge square wave.

Although Controller 125 of FIG. 3 is depicted as a general purpose computer that is programmed to perform various control functions in accordance with the present invention, the invention may be implemented in hardware such as, for example, an application specific integrated circuit (ASIC). As such, it is intended that processor 125, as described herein, be broadly interpreted as being equivalently performed by hardware, software, or by a combination thereof.

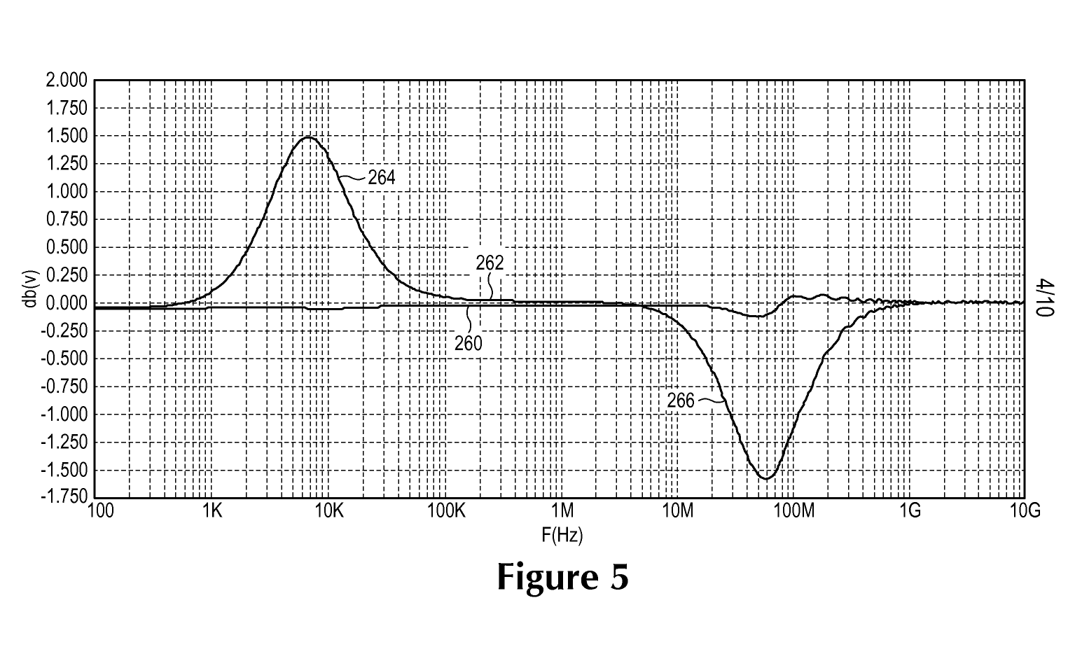

FIG. 4 is a representative schematic diagram of the low capacitance signal acquisition system 200 according to the present invention. Like elements from FIG. 3 are labeled the same. The signal acquisition probe 105 has a probing head 202 containing low capacitance input circuitry in the form of probe tip circuitry 204. The probe tip circuitry 204 has a resistive element 206 in parallel with a capacitive element 208 that is in series with a resistive element 210. The probe tip circuitry 204 is coupled to one end of a coaxial cable 212. The other end of the coaxial cable 212 is coupled to a BNC input 214 of one of the signal acquisition circuitry 115 via resistive element 216 that terminates the coaxial cable 212 in its characteristic impedance. The coaxial cable is preferably a resistive center conductor coaxial cable having a resistance of 39 Ω/ft. The BNC input 214 is coupled via a resistive element 218 to a switching circuit 220. The BNC input 214 generally has a characteristic impedance of 50 ohms which is terminated by resistive elements 218 and 231. The probe tip circuitry 204 is coupled via switching circuit 200 to input circuitry 226 representatively shown as attenuation circuitry consisting of resistive element 227 in parallel with capacitive element 229 and resistive element 231. The switching circuit 220 has a switching element 222 for selectively coupling the probe tip circuitry 204 to compensation amplifier circuitry 224 via input circuitry 226 or coupling a resistor-capacitor network 228 of resistive element 230 in parallel with capacitive element 232 between the probe tip circuitry 204 and the input circuitry 226. The resistive-capacitive network 228 provides backward compatibility for legacy signal acquisition probes requiring a 1 MΩoscilloscope input impedance. The switching element 222 is preferably a relay switch receiving switching commands from controller 125.

The signal acquisition probe 105 preferably has a memory 234 containing information about the probe, such as probe type, serial number, and the like, and may also contain probe calibration data. The probe memory 234 is preferably a one wire EEPROM, manufactured and sold by Maxim Integrated Products, Inc., Sunnyvale, Calif. under Part No. DS2431. The probe memory 234 is coupled to the controller 125 via a one line communications/power line 236. Alternately, the probe memory 234 may communicate with the controller 125 via multi line communications bus, such as an I²C, a Firewire bus and the like.

The compensation amplifier circuitry 224 has a compensation amplifier 238 having its inverting input coupled to the attenuation circuitry 226 and the non-inverting input coupled to ground. The compensation amplifier 238 has feedback loop circuitry 240 that includes an adjustable feedback resistor 242, adjustable resistive and capacitive elements, and an adjustable gain element. The values of the adjustable resistors, capacitor, and gain element are controlled by changing register values of a plurality of registers. The feedback loop of resistive element 242 sets the DC and low frequency gain. Series feedback loops consisting of resistive element 250 and capacitive element 252 and resistive element 254 and capacitive element 256 are adjusted to form a split pair of poles and zeros. The total capacitance of the capacitive elements 252 and 256 set the midband gain and the parallel conductance of the resistive elements 250 and 254 set the high frequency gain. The time constant formed by pole and zero pair formed by elements 250 and 252 can be adjusted independently of the time constant formed by pole and zero pair formed by elements 254 and 256 that is adjusted to provide flatness correction for that portion of the residual error caused by the mismatch of mid and high frequency gains in other portions of the circuit. The series feedback loop of resistive element 244, capacitive element 246 and a variable gain voltage source in the form of a variable gain amplifier 248 having a gain “K” sets the gain in a narrow band between the low and middle band frequencies that is adjusted to provide flatness correction for that portion of the residual error caused by the mismatch of low and mid frequency gains in other portions of the circuit. The controller 125 communicates with the feedback loop circuitry 240 via a four line Serial Peripheral Interface bus 258 for loading register values for the adjustable resistive, capacitive and gain elements.

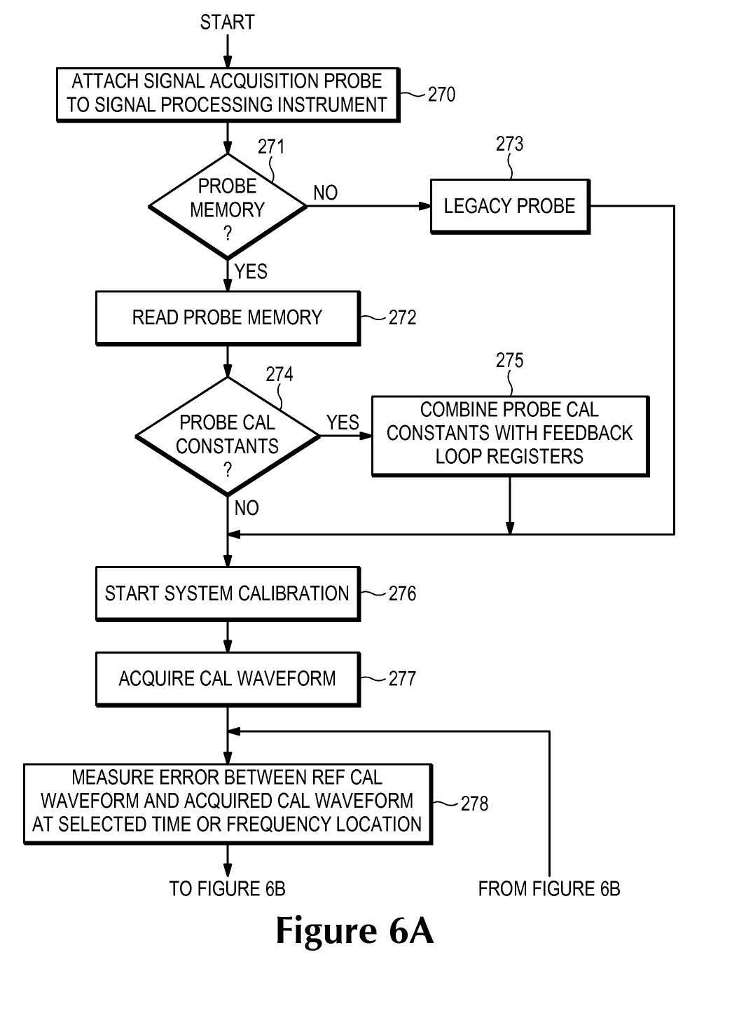

FIG. 5 shows representative frequency responses 260, 262 of the low capacitance signal acquisition system 200 with and without feedback crossover compensation. The low capacitance signal acquisition system 200 reduces the input capacitance in the probe tip circuitry 204 which increases the high frequency input impedance. This breaks the traditional probe-oscilloscope structure where each stage of the signal path is compensated for flat frequency and phase response. The capacitance of the capacitive element 208 in the probe tip circuitry 204 is reduced causing time constant mismatches with the cable 212 and the oscilloscope input circuitry 226 which produce a peak 264 near 8 KHz and a valley 266 near 60 MHz in the frequency response 262. The feedback loop circuitry 240 provides feedback crossover compensation to the peak 264 and valley 266. The 8 KHz peak 264 is corrected in the feedback loop circuitry 240 of the compensation amplifier 238 by changing register values for adjustable resistive element 244, adjustable capacitive element 246, and the gain “K” of the variable gain amplifier 248. The valley 266 near 60 MHz is caused by the capacitance of the capacitive element 208 being lower than the capacitance of the same capacitor in the traditional probe, and is corrected by changing register values for capacitive elements 252 and 256 with resistive elements 250 and 254 forming a split pair of poles and zeros. The total capacitance of capacitive elements 252 plus 256 sets the midband gain (10 KHz to 10 MHZ), and the parallel conductance of resistive elements 250 and 254 sets the gain above 200 MHZ.

The resistive element 244 and the capacitive element 246 in the feedback loop of the compensation amplifier 238 produces a pole-zero pair in the low capacitance signal acquisition system 200 that generates enough degrees of freedom that the peak 264 near 8 KHz in the frequency response can be flattened. The addition of a pole-zero pair in the feedback loop in series with the arbitrary gain “K” can cancel either a peak or a valley by setting “K” to be either positive or negative. The transfer function for the low frequency band (DC to low band AC) is shown by Equation 1 below:

$$H ( jw ) = \frac{{R}_{242} \cdot ( {C}_{Z} \cdot {A}_{z} \cdot {T}_{z} )}{{TA}_{P} \cdot {C}_{P}} \qquad EQ . 1$$

where

C_{Z} represents the Correction Zero pole:
(C₂₄₆·R₂₄₄·jw+1)

A_{X} represents the Attenuator Zero:
(C₂₂₉·R₂₂₇·jw+1)

T_{Z} represents the Tip Zero:
(C₂₀₈·R₂₀₆·jw+1)

C_{P} represents the Correction Poles:

$$( \begin{matrix}( {C}_{252} + {C}_{256} ) \cdot {R}_{242} \cdot jw + {C}_{246} \cdot {R}_{244} \cdot jw + {C}_{246} \cdot K \cdot {R}_{242} \cdot jw + \\ ( {C}_{252} + {C}_{256} ) \cdot {C}_{246} \cdot {R}_{242} \cdot {R}_{244} \cdot {( jw )}^{2} + 1\end{matrix} )$$

TAₚ represent the Tip/Attenuator Pole:
(R₂₂₇+R₂₀₆+C₂₁₂·R₂₂₇·R₂₀₆·jw+C₂₂₉·R₂₂₇·R₂₀₆·jw+C₂₀₈·R₂₂₇·R₂₀₆·jw)
   This 3^{rd} order system has enough degrees of freedom to line up all three poles with all three zeros and allow an arbitrary mismatch of time constants between the tip and the attenuator. The component values for R₂₄₄, C₂₄₆, or “K” can be solved if one of them is set. For most practical values, setting the location of the Correction Zero “C_{Z}” on the real axis of a pole-zero map equal to the location of the Tip/Attenuator Pole “TA_{P}” yields the value for R₂₄₄ if C₂₄₆ is set, or for C₂₄₆ if R₂₄₄ is set. Factoring the Correction Poles “C_{P}” equation and setting the lower of the two poles equal to the Tip Zero “T_{Z}” yields the value of “K” depending on the solved values for R₂₄₄ and C₂₄₆. Alternately, factoring the Correction Poles “C_{P}” equation using the higher solved pole equal to the Attenuator Zero “A_{Z}” yields the value of “K”.

The transfer function for the midband AC to high frequency AC is shown by Equation 2 below:

$$H ( jw ) = \frac{A}{B + C} \qquad EQ . 2$$

where A equals:

$$\frac{1}{( \frac{1}{( {R}_{250} + \frac{1}{{C}_{252} wj} )} + \frac{1}{( {R}_{254} + \frac{1}{{C}_{256} wj} )} )}$$

B equals:

$$( {R}_{231} + \frac{1}{{C}_{229} wj} ) \cdot [ cos ( β \cdot l ) + {Y}_{0} \cdot j \cdot sin ( β \cdot l ) \cdot ( {R}_{210} + \frac{1}{{C}_{208} wj} ) ]$$

C equals:

$$cos ( β \cdot l ) \cdot ( {R}_{210} + \frac{1}{{C}_{205} wj} ) + {Z}_{0} \cdot j \cdot sin ( β \cdot l )$$

and: β=\sqrt{LC}:

$${Z}_{0} = \sqrt{\frac{R + j \cdot w \cdot L}{G + j \cdot w \cdot C}} ; {Y}_{0} = \frac{1}{{Z}_{0}} ;$$

l=electrical length of the cable

The analysis to determine the transfer function through the cable at midband AC to high frequency AC uses a 2-port microwave theory, specifically the ABCD, or transmission matrix. The use of the transmission matrix allows the use of measured data for the cable, since S-parameters can be easily transformed T-parameters. The transfer function is built up by solving for the port voltages. The 2-port method easily solves the transfer function of the probe tip, cable and attenuator. The active circuit in the low capacitance signal acquisition system 200 is solved by summing the current at the summing node and assuming an ideal operational amplifier for the compensation amplifier 238.

The transfer function of Equation 2 indicates that the time delay of the cable causes a pole split between the tip time constant and the attenuator time constant. Traditionally, this pole split is compensated for by choosing values for the probe tip circuitry time constant that set the poles atop of one another. However, this is at odds with the low capacitance signal acquisition system 200 concept where the load capacitance in the probe tip circuitry 204 is reduced by lowering the probe tip capacitance.

The poles may be lined up with each other by increasing the tip resistance but this causes the overall frequency response of the probe-signal processing instrument system to suffer. Other traditional solutions to resolving the midband frequency response flatness requires adjusting cable parameter or removing capacitance in the attenuator to adjust the attenuator time constant. Removing to much capacitance in the attenuator causes the noise gain of the system to suffer and the input amplifier is required to have a higher gain bandwidth. The present invention adds a pole in the transfer function to compensate for the split poles resulting in the splitting of the pole-zero pair in the feedback loop circuitry 240 into two pole-zero pairs (capacitive elements 252, 256 and resistive elements 250 and 254).

The above analysis of the transfer functions for the low frequency band (DC to low band AC) and the midband AC to high frequency AC assumes that there are no parasitic capacitances or inductances, the compensation amplifier 238 is an ideal amplifier with infinite gain-bandwidth, and the series resistance in the cable and the capacitive elements are ignored because they are very small compared to the parallel resistive elements. The resistive elements 210, 231, 250 and 254 in the Equation 2 for the midband AC to high frequency AC are damping resistors in series with the respective capacitive elements 208,229, 252 and 256. It is assumed at these frequencies (midband AC to high frequency AC) that the conductance of the capacitive elements 208,229, 252 and 256 is much higher than the large DC resistive elements 206, 227 and 242, resulting in the midband range being a function of capacitance ratio of 208,229, 252 and 256.

It should be understood that there will be poles due to parasitics and high frequency losses due to skin elects on the cable, as well as zeros from inductive peaking if a ground lead and the various interconnects in the system 200. The compensation amplifier 238 will have a finite bandwidth and phase delay. These additional effects will need to be considered in a final design and will affect the chosen component values for the system 200.

Active compensation of the low capacitance signal acquisition system 200 of the present invention is achieved by electronically varying register values of the resistive and capacitive elements and the gain “K” of the variable voltage amplifier in the feedback loop circuitry 240 of the compensation amplifier 238. The probe memory 234 may be loaded with typical values associated with a low capacitance signal acquisition probe, such as input resistance, attenuation factor, dynamic range, bandwidth host resistance, and the like. The probe memory 234 may also be loaded with calibration constants associated with that particular probe at the time of factory calibration. The calibration constants are register values that are combined with existing register value in the feedback loop circuitry 240 of the compensation amplifier 238.

The fast edge square wave signal from the signal source 157 is provided internally to at least one of the signal channels of the oscilloscope 100 during factory calibration. The fast edge square wave is characterized and stored in oscilloscope memory 155 as a CAL REFERENCE WAVEFORM. The characterized waveform may be digitized magnitude values of the fast edge square wave signal at selected time locations. Alternately, the characterized waveform may be stored as a time domain mathematical expression associated with amplitude, offset, rise time, overshoot aberrations and the like that would generate a digital waveform of the CAL REFERENCE WAVEFORM. A further alternative is characterizing the CAL REFERENCE WAVEFORM in the frequency domain by performing a Fast Fourier Transform (FFT) on the acquired digital time domain data of the fast edge square wave. S-parameter values are generated characterizing the CAL REFERENCE WAVEFORM. Further, both the digital values of the time domain fast edge square wave signal and the frequency domain representation of the fast edge square wave signal may be converted to digital values representing the impulse response of the fast edge square wave signal. CAL REFERENCE WAVEFORMS may also be characterized and stored in oscilloscope memory 155 for each signal channel of the oscilloscope 100. It is contemplated that the fast edge square wave be characterized for each signal channel of the oscilloscope 100 and stored in oscilloscope memory 155 to provide greater measurement accuracy for each signal channel.

The oscilloscope memory 155 is loaded with a series of time specific measured error factor tables. Each table defines a time location from a reference time location on the CAL REFERENCE WAVEFORM. Each table has a measured error field and a measured error factor field with each record of the measured error field having a corresponding record in the measured error factor field. Alternately, the oscilloscope memory 155 may be loaded with a series of frequency specific measured error factor tables where the digital data of the fast edge square wave signal has been converted to the frequency domain using an FFT. Each table defines a frequency location on the CAL REFERENCE WAVEFORM. Each table has a measured error field and a measured error factor field with each record of the measured error field having a corresponding record in the measured error factor field.

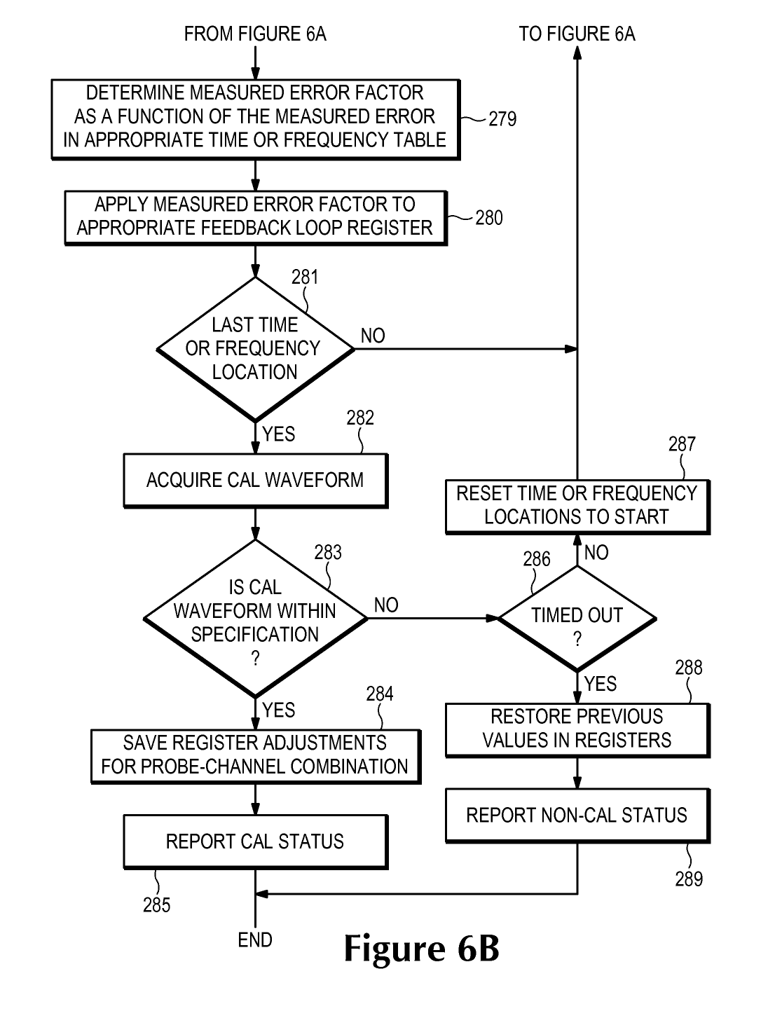

FIGS. 6A and 6B show a calibration process flow chart for calibrating the low capacitance signal acquisition system 200 of the present invention. Prior to the calibration of the signal acquisition probe 105, DC signal path compensation is performed on the signal channel without the signal acquisition probe 105 attached. The signal acquisition probe 105 is attached to one of the signal channels of the oscilloscope 100 at step 270. The oscilloscope 100 detects the presence of a low capacitance signal acquisition probe memory 234 at step 271 and reads the contents of the probe memory 234 at step 272. If the oscilloscope 100 does not detect the presence of a low capacitance signal acquisition probe memory 234, then the attached probe is identified as a legacy probe at step 273. If the probe memory 234 has probe calibration constants as depicted at step 274, then the probe calibration constants are combined with the registers values of the feedback loop circuitry 240 of the compensation amplifier 238 at step 275.

A user connects the other end of the signal acquisition probe 105 to the fast edge square wave signal source 157 and initiates the probe calibration on the signal channel at step 276 using the display device 135 and instrument controls that may include I/O circuitry, such as a keyboard, mouse or the like. The oscilloscope 100 acquires digital values of the fast edge square wave as a CAL WAVEFORM at step 277. Alternately, the acquired digital values of the fast edge square wave may be converted to the frequency domain using an FFT. The error value between the acquired CAL WAVEFORM and the CAL REFERENCE WAVEFORM is measure at a selected time or frequency location as represented in step 278. The measured error factor tables are accessed in step 279 with the selected time or frequency table corresponding to the selected time or frequency of the measured error value being used. The measured error factor is applied to the register value of the appropriate feedback loop register at step 280. The measured error factor is preferably a value that is multiplied with the current register value of the feedback loop circuitry 240 to generate a new register value. At step 281, a determination is made if the measured error value is at the last time or frequency location of the CAL REFERENCE WAVEFORM. If calibration process is not at the last time or frequency location of the CAL REFERENCE WAVEFORM, then the process returns to step 278 and the measured error value between the CAL WAVEFORM and the CAL REFERENCE WAVEFORM at the next selected time or frequency location is determined.

If the calibration process has determined the last measured error value between the CAL WAVEFORM and the CAL REFERENCE WAVEFORM, then a new acquisition of digital values of the fast edge square wave is performed and the digital values are stored as the CAL WAVEFORM as shown in step 282. The just acquired CAL WAVEFORM is compared to calibration specification to determine if the new CAL WAVEFORM is within the calibration specifications at step 283. The calibration specifications includes verifying that the CAL WAVEFORM low frequency compensation measurements are within spec, the peak-to-peak short term aberrations are less than a set time and less than set percentage as compared to the CAL REFERENCE WAVEFORM, the peak-to-peak long term aberrations are greater than a set time and less than set percentage as compared to the CAL REFERENCE WAVEFORM, and the rise time is less than a set time as compared to the CAL REFERENCE WAVEFORM. If the new CAL WAVEFORM meets the calibration specifications, the register values of the feedback loop circuitry 240 of the compensation amplifier 238 are saved for the specific probe and signal channel calibration as shown at step 284. The user is informed that the calibration process has passed by a display output on the display device 135 at step 285 and the calibration process ends.

If the new CAL WAVEFORM does not meet the calibration specification, then the current elapsed time of the calibration process is compared to a timed out value at step 286. If the current elapsed time of the calibration process does not exceed the timed out value, then the time or frequency location of the new CAL REFERENCE WAVEFORM is reset to the start location at step 287 and the measured error values between the CAL REFERENCE WAVEFORM and the new CAL WAVEFORM are determined, the measured error factors are determined and the measured error factors are applied to the register values of the plurality of registers in the feedback loop circuitry 240 of the compensation amplifier 238. If the elapsed time of the calibration process exceeds the timed out value, then the initial register values of the feedback loop circuitry 240 are set as the register values as shown in step 288. The initial register values may be the initial nominal values applied to the registers in the feedback loop circuitry 240 without any probe calibration or the previous calibrated register values if the probe and signal channel combination had been previous calibrated. The user is informed of the non-calibration status of the probe-channel combination by a display output on the display device 135 at step 289 and the calibration process ends.

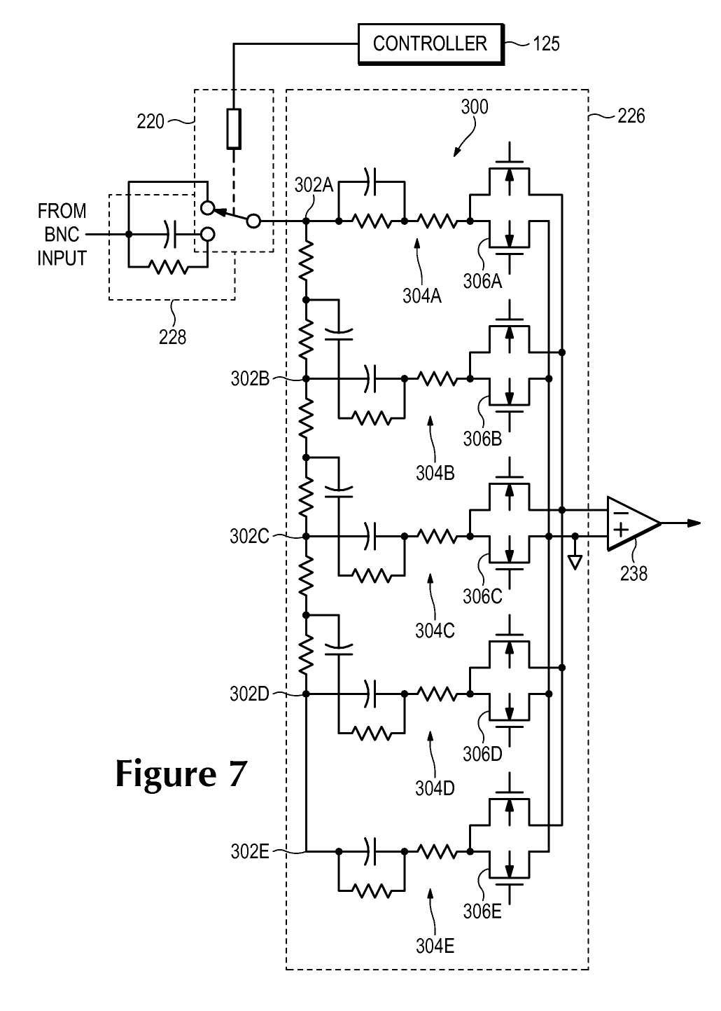

Referring to FIG. 7, there is shown a representative schematic diagram of the attenuation circuitry 226 as implemented in the low capacitance signal acquisition system 200 of the present invention. The attenuator circuitry 226 is preferably a multi-stage attenuation ladder 300 with each attenuation stage having an input current node, 302A, 302B, 302C, 302D, 302E. In the preferred embodiment, the multi-stage attenuation ladder 300 has five stages 304A, 304B, 304C, 304D, 304E. The five attenuation stages are by example only and various numbers of stages may be implemented in the multi-stage attenuation ladder 300 without departing from the scope of the claimed invention. The input current to the multi-stage attenuation ladder 300 is received from the signal acquisition probe 105 via the BNC input 214. The input current is sequentially divided at each input current node, 302A, 302B, 302C, 302D, 302E, of each attenuation stage, 304A, 304B, 304C, 304D, 304E. A first portion of the current at each node is coupled through attenuation switches 306A, 306B, 306C, 306D, 306E to the compensation amplifier 238 and a remaining portion of the current coupled to the next attenuation stage. For example, the input current entering the current input node 302A is divided so that three-fourths of the current is coupled through the first attenuation stage to the compensation amplifier 238 and one-fourth of the current is coupled the input current node 302B of the next attenuation stage 304B. The one-fourth current entering the current input node 302B of the second attenuation stage 304B is divided so that three-sixteenths of the total input current to the multi-stage attenuation ladder 300 is coupled through the second stage 304B to the input of compensation amplifier 238 and one-sixteenth is coupled to the input current node 302C of the next attenuation stage 304C. The one-sixteenth current entering the current input node 302C of the third attenuation stage 304C is divided so that three-sixty-fourths of the total input current to the multi-stage attenuation ladder 300 is coupled through the third stage 304C to the input of compensation amplifier 238 and one-sixty-fourth is coupled to the input current node 302D of the next attenuation stage 304D. The one sixty-fourth current entering the input current node 302D is divided so that one-half of the current is coupled through the fourth stage 304D to the input of compensation amplifier 238 and one-half is coupled through the fifth stage 304E to the input of the compensation amplifier 238.

Vertical gain settings input by a user are interpreted by the controller 125 for activating and deactivating the attenuation switches 306A, 306B, 306C, 306D, 306E. The current through each of the attenuator stages 304A, 304B, 304C, 304D, 304E may be individually coupled to the input of the compensation amplifier 238 or the current through multiple stages maybe combined and applied to the input of the compensation amplifier 238. The attenuation circuitry 226 scales the current to the dynamic range of the compensation amplifier 238.

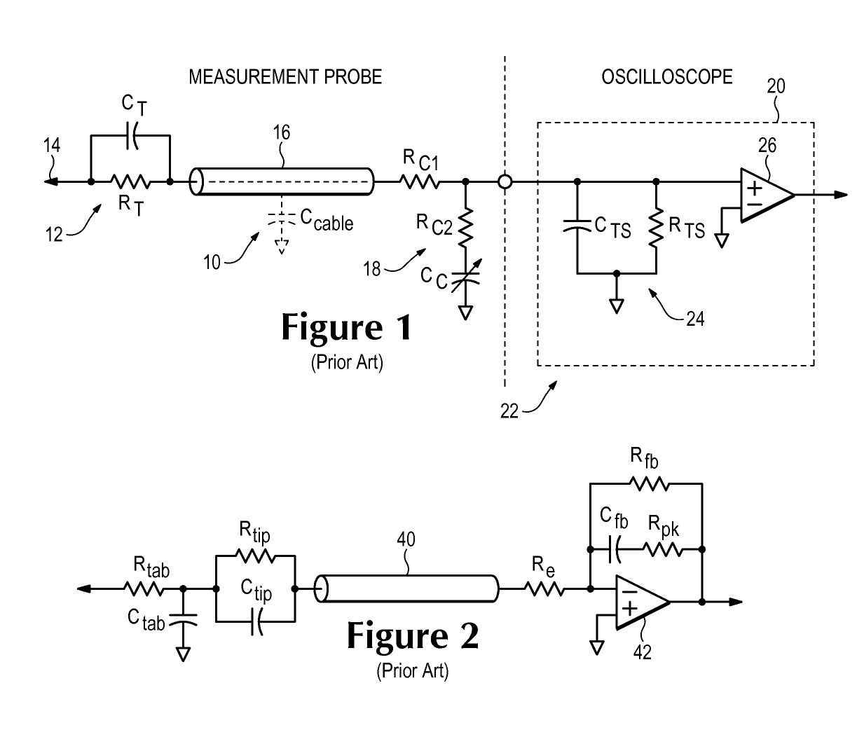

The input impedance of the attenuator circuitry 226 for the low capacitance signal acquisition system 200 is lower than in existing passive voltage probes. The shunt impedance of the compensation circuitry 18 in the compensation box of the prior art probe as illustrated in FIG. 1 is now a series impedance in the low capacitance signal acquisition system 200. The addition of the selectable resistive-capacitive network 228 in series with the signal acquisition probe 105 and the attenuation circuitry 226 lowers the input capacitance of the oscilloscope to allow legacy passive voltage probes to be used with the low capacitance signal acquisition system 200.

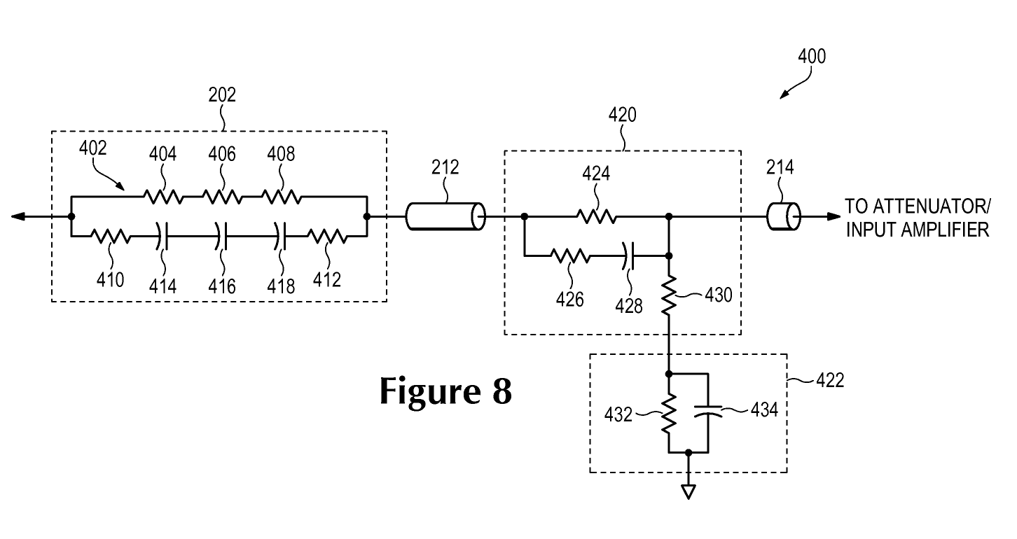

Referring to FIG. 8, there is shown a schematic representation of the signal acquisition probe 105 implementing a high voltage probe 400 for the low capacitance signal acquisition system 200. The high voltage probe 400 has a probing head 202 containing probe tip circuitry 402. The probe tip circuitry 402 has a plurality of series connected resistive elements 404, 406, 408 coupled in parallel with series connected resistive elements 410 and 412 and capacitive elements 414, 416 and 418. The probe tip circuitry is coupled to one end of coaxial cable 212 with the other end of the coaxial cable coupled via coaxial cable termination circuitry 420 to shunt attenuation circuitry 422 and the BNC input of one of the signal acquisition circuitry 115. The cable termination circuitry 420 has resistive element 424 coupled in parallel with resistive element 426 and capacitive element 428 which are in series with resistive element 430. The shunt attenuation circuitry 422 has a resistive element 432 in parallel with a capacitive element 434. The shunt attenuation circuitry 422 functions as a portion of a voltage divider network with the probe tip circuitry 402. In a preferred embodiment, the total series resistance of the probe tip circuitry 402 is approximately 40 MΩ and the shunt resistive element 432 is 1 MΩ which results in a divide by ratio of 40:1 and a total attenuation factor from the probe tip circuitry 402 to the output of the compensation amplifier of 50. The voltage divider network of the probe tip circuitry 402 and the shunt attenuation circuitry 422 reduces the high voltage potential at the output of the coaxial cable 212 to provide a safety factor for a user.

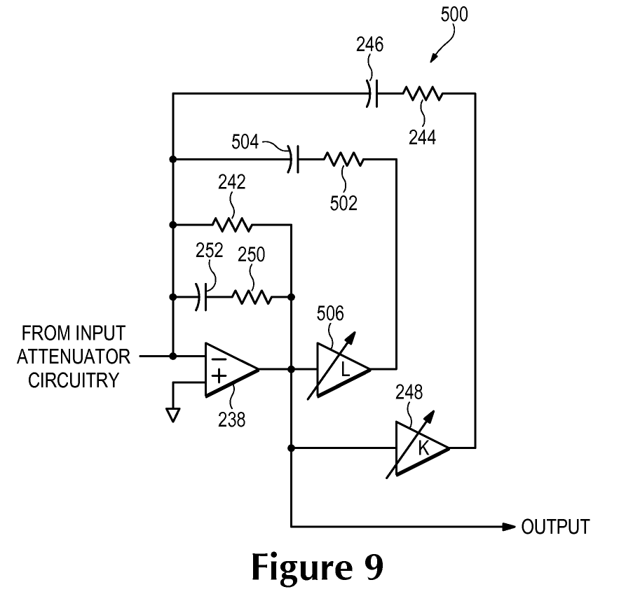

The low capacitance signal acquisition system 200 has been described using a compensation amplifier having feedback loop circuitry 240 that includes pole and zero pair, split pairs of poles and zeros, and a series feedback loop of resistive element 244, capacitive element 246 and a variable gain voltage source in the form of a variable gain amplifier 248 having a gain “K”. Various alternative embodiments are contemplated as shown representatively shown in FIG. 9. The low capacitance signal acquisition system circuitry prior to the compensation amplifier 238 is the same as in FIG. 4. Common elements from previous drawing figures are labeled the same in FIG. 9. The resistive element 254 and capacitive element 256 in the feedback loop circuitry 240 of FIG. 4 may be replaced in feedback loop circuitry 500 with a series feedback loop of resistive element 502, capacitive element 504 and a variable gain voltage source 506 in the form of a variable gain amplifier having a gain “L”. The addition of the second variable voltage gain source 506 provides another degree of freedom that allows the adjustment of the pole and zero using the gain “L” without varying the time constant of the series resistive and capacitive elements 502 and 504. The series feedback loop of the resistive and capacitive elements 502, 504 and the variable gain voltage source 506 in conjunction with the series resistive element 250 and capacitive element 252 are adjusted to provide flatness correction for that portion of the residual error caused by the mismatch of mid and high frequency gains in other portions of the circuit. As with the circuit of FIG. 4, the values of the adjustable resistors, capacitor, and gain element are controlled by changing register values of a plurality of registers with the controller 125 loading register values for the adjustable resistive, capacitive and gain elements.

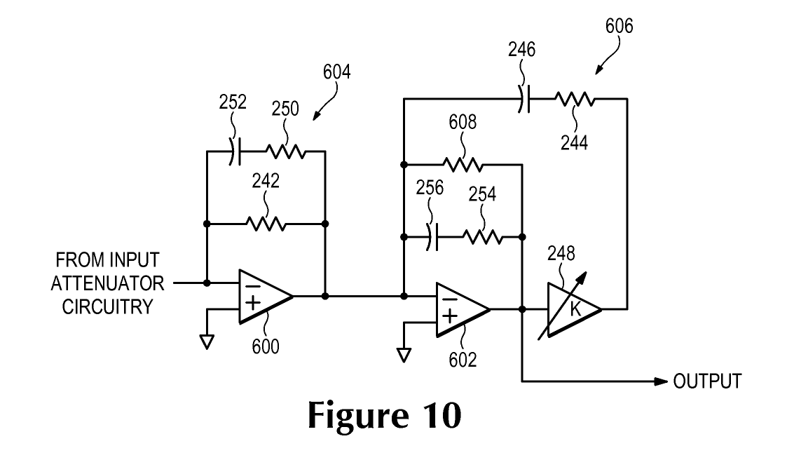

A further embodiment of the low capacitance signal acquisition system 200 is representatively shown in FIG. 10 where the compensation amplifier 238 of FIG. 4 has been replaced with a first amplifier 600 and a second amplifier 602. The feedback loop circuitry 240 of FIG. 4 has been divided between first amplifier 600 and the second amplifier 602. Common elements from previous drawing figures are labeled the same in FIG. 9. The feedback loop circuitry 604 of amplifier 600 has resistive element 242 that sets the low band gain, capacitive element 252 that sets the midband gain and resistive element 250 that set the high band gain. The feedback loop circuitry 606 of amplifier 602 has a feedback resistive element 608 that provides amplifier 602 with a DC/low frequency feedback path. The resistive element sets the low to mid-frequency of the amplifier 602 stage, and sets the overall DC to low frequency gain of the multiple amplifier system in conjunction with resistive element 242. The series feedback loop of resistive element 244, capacitive element 246 and a variable gain voltage source, in the form of a variable gain amplifier 248 having a gain “K”, sets the gain in a narrow band between the low and middle band frequencies that is adjusted to provide flatness correction for that portion of the residual error caused by the mismatch of low and mid frequency gains in other portions of the circuit. Resistive element 254 in series with capacitive element 256 form a pole and zero pair that is adjusted to provide flatness correction for that portion of the residual error caused by the mismatch of mid and high frequency gains in other portions of the circuit. As with the previous embodiments, the values of the adjustable resistors, capacitor, and gain element are controlled by changing register values of a plurality of registers with the controller 125 loading register values for the adjustable resistive, capacitive and gain elements.

It will be obvious to those having skill in the art that many changes may be made to the details of the above-described embodiments of this invention without departing from the underlying principles thereof. The scope of the present invention should, therefore, be determined only by the following claims.

What is claimed is:

1. A low capacitance signal acquisition system comprising:
a signal acquisition probe having a low capacitance input circuit;
a signal processing instrument having input circuitry coupled to a compensation amplifier disposed in the signal processing instrument; and
a signal cable coupling the low capacitance input circuit to the input circuitry of the signal processing instrument;
wherein the low capacitance input circuit, the signal cable and the signal processing instrument input circuitry have mismatched time constants with the compensation amplifier having feedback loop circuitry providing adjustable gain and pole-zero pairs for maintaining flatness over the low capacitance signal acquisition system frequency bandwidth.

2. The low capacitance signal acquisition system as recited in claim 1 wherein the feedback loop circuitry further comprises a plurality of registers for setting resistive values and capacitive values of respective resistive and capacitive elements and a voltage of at least a first variable gain voltage source.

3. The low capacitance signal acquisition system as recited in claim 1 wherein the low capacitance input circuit further comprises at least a first resistive element in parallel with a capacitive element.

4. The low capacitance signal acquisition system as recited in claim 1 wherein the low capacitance input circuit further comprises a plurality of first resistive elements in parallel with a plurality of capacitive elements.

5. The low capacitance signal acquisition system as recited in claim 1 wherein the compensation amplifier further comprises an inverting amplifier.

6. The low capacitance signal acquisition system as recited in claim 2 wherein the variable gain voltage source in the compensation amplifier feedback loop circuitry is coupled in series with at least a first resistive element and a first capacitive element.

7. The low capacitance signal acquisition system as recited in claim 2 wherein the variable gain voltage source in the compensation amplifier feedback loop circuitry comprises a variable gain voltage amplifier.

8. The low capacitance signal acquisition system as recited in claim 2 wherein the compensation amplifier feedback loop circuitry further comprises a second series coupled capacitive and resistive elements in parallel with a third series coupled capacitive and resistive elements forming a split pair of poles and zeros.

9. The low capacitance signal acquisition system as recited in claim 2 wherein the compensation amplifier feedback loop circuitry further comprises a second variable gain voltage source coupled in series with at least a second resistive element and a second capacitive element and a series coupled third capacitive element and third resistive element.

10. The low capacitance signal acquisition system as recited in claim 9 wherein the second variable gain voltage source in the compensation amplifier feedback loop circuitry comprises a variable gain voltage amplifier.

11. The low capacitance signal acquisition system as recited in claim 2 wherein the compensation amplifier further comprises a first amplifier coupled to the input circuitry and having a first feedback loop providing adjustable low capacitance signal acquisition system gain and a second amplifier coupled to the output of the first amplifier having feedback loop circuitry providing poles-zero pairs for maintaining flatness over the low capacitance signal acquisition system frequency bandwidth.

12. The low capacitance signal acquisition system as recited in claim 1 wherein the input circuitry further comprises attenuator circuitry.

13. The low capacitance signal acquisition system as recited in claim 12 further comprising a switching circuit disposed in the signal processing instrument for selectively coupling the low capacitance input circuit to the compensation amplifier via the attenuation circuitry and for selectively coupling a resistive-capacitive network between the low capacitance input circuit and the attenuation circuitry.

14. A calibration process for a low capacitance signal acquisition system having a signal acquisition probe and a signal processing instrument comprising the steps of:
a) acquiring digital values of a fast edge signal as a calibration waveform using the signal acquisition probe and the signal processing instrument;
b) determining a measured error value between a fast edge signal reference calibration waveform stored in the signal processing instrument and the calibration waveform at a common location on the waveforms set by at least one of a time location and a frequency location;
c) determining a measured error factor as a function of the measured error value and the common location on the waveforms;
d) applying measured error factor to a register value of an appropriate register in a plurality of registers in feedback loop circuitry of a compensation amplifier;
e) repeating steps b), c), and d) for additional common locations on the waveforms;
f) acquiring digital values of a fast edge signal as a calibration waveform using the signal acquisition probe and the signal processing instrument after determining the measured error value and measured error factor at the last common location on the waveform;
g) comparing calibration specifications with the calibration waveform acquired in step f) to verify the calibration waveform is within calibration specifications;
h) storing register values loaded in the plurality of registers in feedback loop circuitry of a compensation amplifier for the calibration waveform within calibration specifications; and
i) displaying successful result of the calibration process.

15. The calibration process for a low capacitance signal acquisition system having a signal acquisition probe and a signal processing instrument as recited in claim 14 wherein the verifying step further comprises the steps of:
a) determining if the calibration process has exceeded a timed out value;
b) setting the common location on the waveforms to the initial location when the calibration process has not exceeded the timed out value;
c) repeating step e) for the common locations on the waveforms.

16. The calibration process for a low capacitance signal acquisition system having a signal acquisition probe and a signal processing instrument as recited in claim 15 wherein the determining step of claim 10 further comprises the steps of:
a) storing initial register values in the plurality of registers in the feedback loop circuitry of a compensation amplifier prior to the start of the calibration process when the calibration process exceeds the timed out value; and
b) displaying unsuccessful result of the calibration process.

17. The calibration process for a low capacitance signal acquisition system having a signal acquisition probe and a signal processing instrument as recited in claim 14 wherein the acquiring step of step a) further comprises the steps of:
a) attaching the signal acquisition probe to the signal processing instrument;
b) detecting at least one of the presence or absence of a probe memory in the signal acquisition probe by the signal processing instrument;
c) loading stored contents of probe memory into the signal processing instrument when the probe memory is present;
d) detecting probe calibration constants stored in the probe memory;
e) applying the probe calibration constants to appropriate register values in the plurality of registers in the in feedback loop circuitry of a compensation amplifier; and.
f) identifying the signal acquisition probe as not having a probe memory when the probe memory is absent.

18. The calibration process for a low capacitance signal acquisition system having a signal acquisition probe and a signal processing instrument as recited in claim 14 wherein the determining step of step b) further comprises the steps of:
a) converting the digital values of a fast edge signal calibration waveform to a frequency domain representation using a Fast Fourier Transform;
b) determining a measured error value between a frequency domain representation of fast edge signal reference calibration waveform stored in the signal processing instrument and the frequency domain representation of the calibration waveform at a common location on the waveforms set by a frequency interval.

19. The calibration process for a low capacitance signal acquisition system having a signal acquisition probe and a signal processing instrument as recited in claim 18 wherein the determining step further comprises the steps of generating S-parameters for the frequency domain representation of the fast edge signal reference calibration waveform.
